(19) United States
(12) Patent Application Publication
(10) Pub. No.: US 2024/0201247 A1
(43) Pub. Date: Jun. 20, 2024

(54) TEST ARRANGEMENT FOR EMULATING THE PHASE CURRENTS OF AN ELECTRIC MOTOR, AND METHOD FOR TESTING A POWER ELECTRONIC CONTROL UNIT

(71) Applicant: dSPACE GmbH, Paderborn (DE)

(72) Inventors: Joerg BRACKER, Paderborn (DE); Daniel EPPING, Paderborn (DE)

(73) Assignee: dSPACE GmbH, Paderborn (DE)

(21) Appl. No.: 18/535,921

(22) Filed: Dec. 11, 2023

(30) Foreign Application Priority Data
Dec. 14, 2022 (DE) 10 2022 133 326.4

(51) Int. Cl. G01R 31/28; G05B 17/02

(52) U.S. Cl. CPC G01R 31/2832; G05B 17/02

(57) ABSTRACT

A test arrangement for emulating phase currents of an electric motor for testing a power electronic control unit. The control unit drives the electric motor and can be connected to the test arrangement. An inductance emulator simulates the electric motor as an electrical load for the control unit via a power electronic circuit, the inductance emulator acting as a current source. A test device influences the phase current of the inductance emulator as a function of an analysis of an output voltage of the control unit. The test device performs the analysis such that the output voltage of the control unit is compared with multiple, preferably three, voltage ranges, and a respective range for a control variable of the phase current is specified depending on the voltage range in which the output voltage of the control unit is located, which control variable is a control voltage of the inductance emulator.

This nonprovisional application claims priority under 35 U.S.C. § 119(a) to German Patent Application No. 10 2022 133 326.4, which was filed in Germany on Dec. 14, 2022, and which is herein incorporated by reference.

### BACKGROUND OF THE INVENTION

### Field of the Invention

The application relates to a test arrangement for emulating the phase currents of an electric motor for testing a power electronic control unit and to a method for testing a power electronic control unit.

### Description of the Background Art

Devices for carrying out control and/or regulating tasks in vehicles are also referred to as control units. Control units in vehicles, in particular motor vehicles, can have a computing unit, memory, interfaces, and possibly other components, that are necessary for the processing in the control unit of input signals with input data and the generation of control signals with output data. The interfaces serve to receive input signals or to deliver control signals.

There is a so-called motor control unit in battery electric vehicles, by which means the drive motor is supplied with electric energy from a battery, in particular a traction battery. The motor control unit has an inverter that converts DC voltage provided by the battery into AC voltage with which the motor is supplied.

In order to test the motor control unit, emulators are provided, which simulate the behavior of the motor by the means that electric currents that simulate the phase currents of the different windings of the motor are provided to the motor control unit.

If the inverter of the motor control unit is switched off or if the semiconductor power switches are switched to a non-conducting state for another reason, then this state is called the inactive state of the inverter or inverter lockout. Realistic emulation of the motor for this state is desired.

### SUMMARY OF THE INVENTION

It is therefore an object of the invention to provide a test arrangement for emulating the phase currents of an electric motor for testing a power electronic control unit that is equipped to drive the electric motor and can be connected to the test arrangement.

In an example, the test arrangement has: an inductance emulator that simulates the electric motor as an electrical load for the control unit by means of a power electronic circuit, wherein the inductance emulator acts as a current source with a phase current as output current; and a test device that is equipped to influence the phase current of the inductance emulator as a function of an analysis of an output voltage of the control unit, wherein the test device is equipped to carry out the analysis in such a manner that the output voltage of the control unit is compared with multiple, preferably three, voltage ranges, and a respective range for a control variable of the phase current is specified depending on the voltage range in which the output voltage of the control unit is located. The control variable of the phase current is preferably a control voltage of the inductance emulator that influences the phase current.

Such a test arrangement for emulating the phase currents can also be referred to as a simulator, in particular a power-hardware-in-the-loop simulator.

In addition, a method is proposed for testing a power electronic control unit that is connected to a test arrangement that is equipped to emulate the phase currents of an electric motor. An inductance emulator is used that simulates the electric motor as an electrical load for the control unit by means of a power electronic circuit, wherein the inductance emulator acts as a current source with a phase current as output current, wherein a test device is used that influences the phase current as a function of an analysis of an output voltage of the control unit, wherein the test device carries out the analysis in such a manner that the output voltage is compared with multiple, preferably three, voltage ranges, and a respective range for a control variable of the phase current is specified depending on the voltage range in which the output voltage is located. The control variable is preferably a control voltage that influences the phase current.

The test arrangement for emulating the phase currents of an electric motor for testing a power electronic control unit and, respectively, the method for testing such a power electronic control unit have the advantage that a switchover between an active and an inactive state of the power electronic control unit is reliably detected through the analysis of the output voltage of the power electronic control unit by means of a comparison with multiple, preferably three, voltage ranges, and the specification dependent thereon of a control variable with which the phase current is ultimately influenced. As a result, automated testing of the power electronic control unit is possible throughout.

A range for the control variable can be specified by the analysis. For control of the phase current by the current regulator, the control variable can be permitted to assume a value only within a certain range. For the control voltage as control variable, this corresponds to a certain voltage range. This voltage range can be specified by the analysis.

An electric motor is simulated as an electrical load by the inductance emulator. The power electronic control unit that is tested by this means can have an inverter with half bridges. The half bridges have power switches that are open in an inactive state. In a real case, which is to say when an electric motor is actually connected to the power electronic control unit, the current in this real inductance decays to zero at some point in the inactive state. As long as energy is still stored in the inductance, a current, a so-called freewheeling current, flows through one of the freewheeling diodes of the inverter in this case. In this case, the freewheeling diodes are each connected in parallel with the power switch, which is to say the transistor, for example. The freewheeling diodes in this case can be designed to be separate from the transistor or integrated into the transistor.

The inductance emulator can simulate this freewheeling current. The inductance emulator can be equipped with a higher voltage than the control unit. Therefore, the inductance emulator can control the freewheeling current through the freewheeling diode in accordance with a setpoint of the emulator, which is to say of a simulation model of the emulator. The test device reads this model value from an associated memory. But when the current has decayed, a current of exactly zero must be controlled by the inductance emulator in order to realistically simulate the behavior of an inductance. The smallest deviation from ideal zero has the result in this case that the freewheeling diode of either the upper or lower transistor of the inverter bridge in the control unit becomes conductive, since there is no other path for this error current. At the same time, however, when a freewheeling diode becomes conductive, the voltage also jumps beyond either the upper or the lower potential of the DC link voltage of the control unit. Owing to the feedback with the model of the inductance emulator, an up-and-down oscillation of the simulated current can occur. As a result, an up-and-down oscillation of the voltage at the control unit, which is to say of the output voltage of the control unit, can also occur. The emulator often cannot distinguish this up-and-down oscillation of the output voltage of the power electronic control unit from normal switching behavior. The emulator often cannot distinguish this up-and-down oscillation of the output voltage of the control unit from normal switching behavior. This is the case especially when the control unit uses discontinuous pulse width modulation patterns, optimized pulse patterns, and/or short pulses for online motor identification, in contrast to a continuous pulse width modulation pattern with a fixed frequency.

The test arrangement serves to emulate the phase currents of an electric motor for testing a power electronic control unit. Such control units are tested comprehensively with such test arrangements. This is why manufacturers or even users of such control units employ such test arrangements. The test arrangements must simulate the components connected to the control unit as well as possible in this case. The present application primarily considers the inactive state of the control unit, which is to say when the power semiconductor switches of the half bridges of the inverter of the control unit are open, and how the test arrangement should properly behave in this case. For this purpose, it is necessary to reliably recognize this state, and this is accomplished according to the teaching of the independent claims.

Particularly in the automotive industry, electric motors that are operated with AC voltage are employed as traction motors for propelling the vehicle. A power electronic control unit is then necessary to drive the motors. This control unit therefore has an inverter or converter that converts DC voltage that comes from the traction battery into an AC voltage. The test arrangement can simulate all necessary phases of the electric motor, which is to say three or six, for example. A converter is a power converter that converts electric power. The power conversion can be made possible in both directions in this case. An inverter can thus also act in the other direction, and convert power both from the battery to the motor and in the reverse direction from the motor to the battery as well. In the first case, the motor is driven and delivers mechanical power to the vehicle. In the second case, the motor is braked and acts as a generator.

For emulation of the phase currents, the test arrangement has the so-called inductance emulator that simulates the electric motor as an electrical load for the control unit by means of a power electronic circuit, wherein the inductance emulator acts as a current source with a respective phase current as output current. In other words, the power electronic circuit is made in such a way that it acts like a current source and sets the respective phase current according to the output voltage of the control unit.

In addition, the test arrangement can have a test device that is equipped such that it can capture, i.e., can measure, the output voltage of the control unit directly or indirectly through a measurement voltage, and influences the phase current of the inductance emulator on the basis of the analysis of this output voltage. The test device therefore has capture means, also called measurement means, to measure the output voltage of the control unit or a measurement voltage that correlates therewith, and analysis means that carry out the analysis of the output voltage. If the inductance emulator already provides the capability of sensing the output voltage, the test device can be designed entirely as software or as hardware and software in order to achieve control of the phase current.

The output voltage of the control unit is compared with multiple voltage ranges in this process, wherein the boundaries of these voltage ranges are stored in a memory. For this purpose, the test device has the appropriate threshold comparator in order to map the output voltage appropriately and thereby to determine the control variable range. The corresponding phase current is influenced with this control variable. In brief, the test device looks at the output voltage of the control unit and identifies, by means of the stored model, which phase current matches this output voltage of the control unit, and then sets it accordingly through the control variable. The control variable is limited here to the specified control variable range.

The power electronic circuit that sets the phase current can be designed as a converter that uses the voltage present at the inductance emulator for generating the alternating current.

The same applies for the method for testing a power electronic control unit.

The performance and/or the result of the analysis depends on the battery voltage that is applied to the control unit, and/or on the voltage present at the inductance emulator. This can mean that the performance of the analysis itself depends on the voltage or voltages and/or that the result of the analysis depends on the voltage or voltages. The battery voltage can be changed for the test arrangement, for example in order to simulate a deteriorating battery. The test arrangement provides the voltage present at the inductance emulator.

It is additionally proposed that the magnitude of the voltage present at the inductance emulator should be greater than the battery voltage.

It is additionally proposed that the circuit can have a converter that is equipped to use at least three different values for the control variable for the current control. This means that the circuit on the side of the inductance emulator is connected as a converter. The converter can be, for example, a multilevel inverter that provides multiple levels for the control variable. It is advantageous here to provide more than two levels.

In this case, provision is additionally made that the converter of the inductance emulator can have three bridge arms connected in parallel to one another, each with four or six power switches, for example. A so-called multilevel converter can be implemented in this way.

The inductance emulator can have an inductance network. The inductance network formed of coupled inductances can have two fundamental functions. Firstly, it is intended to prevent cross-currents between the parallel bridge arms of the circuit. In addition, it serves as an inductive voltage divider in order to combine multiple discrete voltages for multistage bridges. A multistage topology can thus be created with the aid of this voltage divider when bridges with multiple stages are used. The control variable for the phase current is produced at the output of the inductance network. The control variable for the phase current is, in particular, a control voltage in this case.

The test device for the analysis of the output voltage of the control unit can have a threshold comparator that has an upper and a lower threshold value, wherein the test device selects the respective range for the control variable for current control as a function of these threshold comparisons of the output voltage of the control unit. In particular, at least three voltage ranges for the output voltage of the control unit are then defined by the upper and lower threshold values.

The inductance emulator can have a coupling inductance that can be arranged after the inductance network in the direction of the control unit. The output voltage of the control unit is present at the side of the coupling inductance toward the control unit, and the control variable for the current control is present at the side in the direction of the converter. This control variable is preferably the control voltage of the inductance emulator. The control voltage is output by the inductance network, for example, and is present at the coupling inductance. The control variable specifies the control voltage at the coupling inductance in this way. The control voltage at the coupling inductance influences the phase current that is output by the inductance emulator. A positive control voltage increases the phase current here, a negative control voltage reduces the phase current. A high control voltage increases the phase current faster than a lower control voltage.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a block diagram of the test arrangement with a connected control unit and battery,

FIG. 2 shows a simplified circuit diagram of the inductance emulator, the test device, and the control unit,

FIG. 3 shows another circuit diagram of the inductance emulator, the test device, and the control unit,

FIG. 4 shows another circuit diagram of the inductance emulator,

FIG. 5 shows a flowchart of the method according to the patent application, and

FIG. 6 shows an ordinate with the individual voltages.

### DETAILED DESCRIPTION

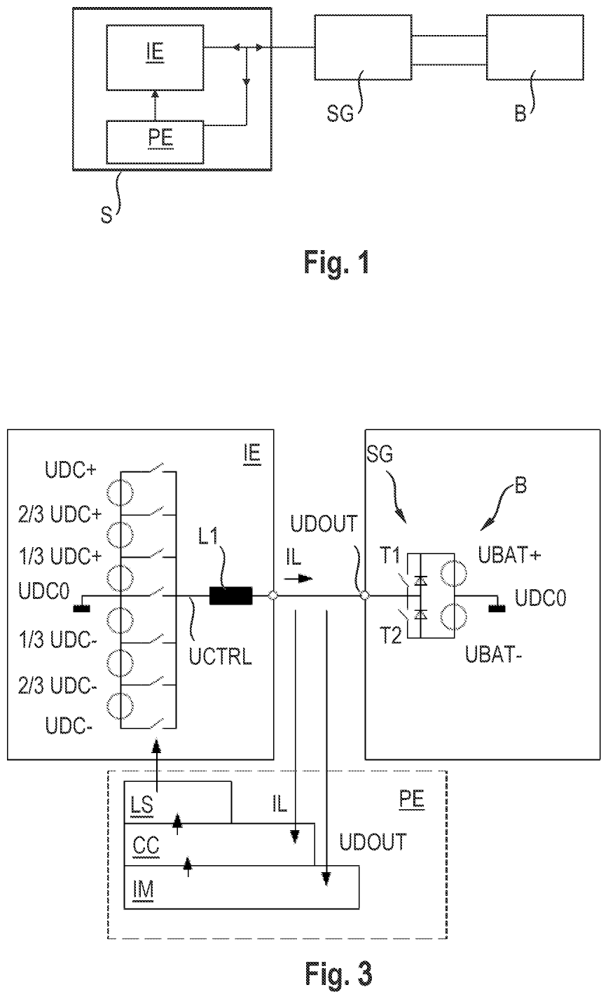

In a block diagram, FIG. 1 shows a test arrangement S with an inductance emulator IE as well as a test arrangement PE and, connected thereto, a control unit SG that is supplied with electric energy by a battery B. The battery B can be a real battery or an emulation of a battery.

The control unit SG is also referred to as “device under test”. The control unit SG, including in combination with the emulated battery B, can be tested with regard to its function by means of the test arrangement S. The control unit SG can be a motor control unit, for example, with which an electric motor, in particular a drive motor of a vehicle, is driven. In particular, electric energy from the battery B can be converted into electric energy for an electric motor by a power converter, which can be designed as an inverter. For an alternating-current motor, in particular, the power converter is designed as an inverter that can also act in the other direction, which is to say as a rectifier, for charging the battery.

In embodiments it is possible that the emulation of the battery with the emulation of the phase currents is carried out by hardware. The power electronic circuit that is used for emulating the phase currents can also emulate the battery B, for example in combination with a capacitor. As a result, a complete emulation environment of the power and signal connections of the control unit can be created. It is an advantage here that the transferred electric energy can remain in the system.

The test arrangement S has the inductance emulator IE for emulating the inductances of the electric motor, wherein these inductances are simulated by a power electronic circuit and this power electronic circuit is controlled or regulated by the test device PE. To do so, the test device PE captures the output voltage UDOUT of the control unit SG and uses it to define, with the aid of stored model data, which output current of the inductance emulator IE, which is to say which phase current IL, matches the output voltage UDOUT of the control unit SG. This phase current IL is then produced by the inductance emulator IE. What is important here is that the test device PE detects whether an inactive state as described above is present on the basis of the output voltage UDOUT of the control unit SG.

In the case that the inactive state is present, the inductance emulator IE emulates a phase current IL that ultimately decays to zero. This is because current will no longer flow after the decay of the freewheeling energy when the half bridges are shut off. This operating condition of the inactive control unit can now be automatically detected and executed with the described test arrangement S. The test arrangement can remain active while the control unit assumes the described inactive state.

For this purpose, the output voltage UDOUT of the control unit SG is compared with at least three voltage ranges. One voltage range is located, e.g., around the reference potential—for example ground or zero—and the other ranges then each adjoin it at the positive and negative values. The boundaries between the ranges are specified by threshold values UThH, UThL, for example. Thus two threshold values UThH, UThL are necessary for three voltage ranges. In this case, a value of 10 V, for example, can be taken and subtracted from the battery voltage UBAT+ on the positive side and added to the battery voltage UBAT− on the negative side in order to specify the value for the two threshold values UThH, UThL. This spacing from the battery voltage has proven to be advantageous. The value can also be chosen to be smaller or larger than 10V, however, and may also be asymmetrical. For example, the threshold value UThH can be spaced away from UBAT+ by a different amount than UThL is spaced away from UBAT−. In other words, UThL can be spaced, e.g., 15 V away from UBAT− and UThH can be spaced, e.g., 20 V away from UBAT+.

The output voltage UDOUT can be measured in this case with reference to UDCO, for example. It is likewise possible to measure the output voltage UDOUT with reference to UBAT+ or UBAT−. The threshold values must then be shifted accordingly.

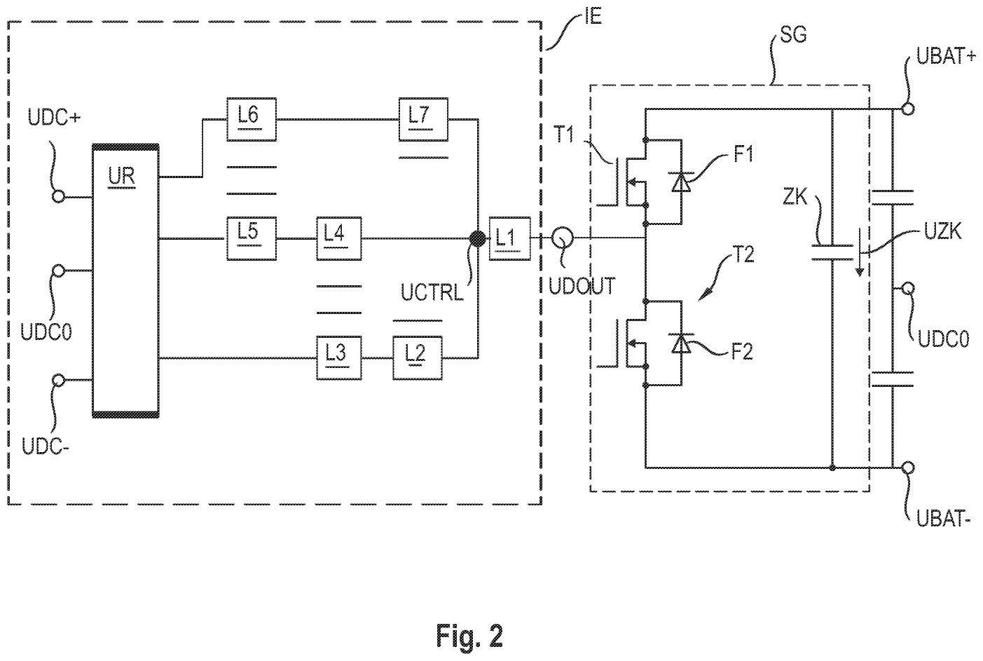

In a circuit diagram, FIG. 2 shows the inductance emulator IE connected to the control unit SG. The battery B in turn is connected by its two potentials, UBAT+ and UBAT−, to the control unit SG on the other side. The emulated battery B is represented by two capacitor symbols and wired to the DC link voltage UZK in parallel with the DC link capacitor ZK. The power electronic control unit SG is connected to the inductance emulator IE for testing. The control unit SG has an inverter with two half bridges. One half bridge connects the positive battery potential UBAT+ to the output potential UDOUT and the other half bridge connects the negative battery potential UBAT− to the output potential UDOUT. The half bridges each have a power switch T1, T2, which are open in an inactive state of the control unit. In the control unit SG, one freewheeling diode F1 and F2 is wired in parallel with each of the two power switches T1 and T2. Through suitable clocked driving of the power switches, the DC voltage provided by the battery B can be converted into AC voltage UDOUT by the inverter with the two half bridges. The inverter can also act as a rectifier in the other direction, for example for charging the battery B.

The battery B can also be emulated. If the battery B is emulated by the same hardware that also includes the inductance emulator IE, then the two respective capacitors between UBAT+ and UDC0 and between UBAT- and UDC0 can be used to emulate the battery voltage UBAT+ relative to UBAT−. For example, additional circuit arrangements such as, e.g., half bridges can be used for this purpose, by which means the battery is emulated so that the battery voltage is modeled across the DC link capacitor.

The output voltage UDOUT of the control unit SG is tapped between the two power switches T1 and T2. The output voltage UDOUT is present between the output of the control unit SG and the input of the inductance emulator IE. In this case the output voltage UDOUT is present directly at the coupling inductance L1. After this coupling inductance L1 in the direction of the inductance emulator IE, the control variable UCTRL is specified by the inductance emulator IE. This control variable UCTRL influences the phase current that the inductance emulator IE delivers to the control unit SG.

Three arms of an inductance network with the inductances L2 to L7—connected to the coupling inductance L1—are depicted in FIG. 2. These inductances L2 to L7 have iron cores. Also depicted—by means of the dashes—are iron cores that are associated with the inductances L2 to L7. The respective inductances L5/L6, L3/L4, and L2/L7 are magnetically coupled through the iron cores. The connection to the control unit SG is accomplished through the coupling inductance L1.

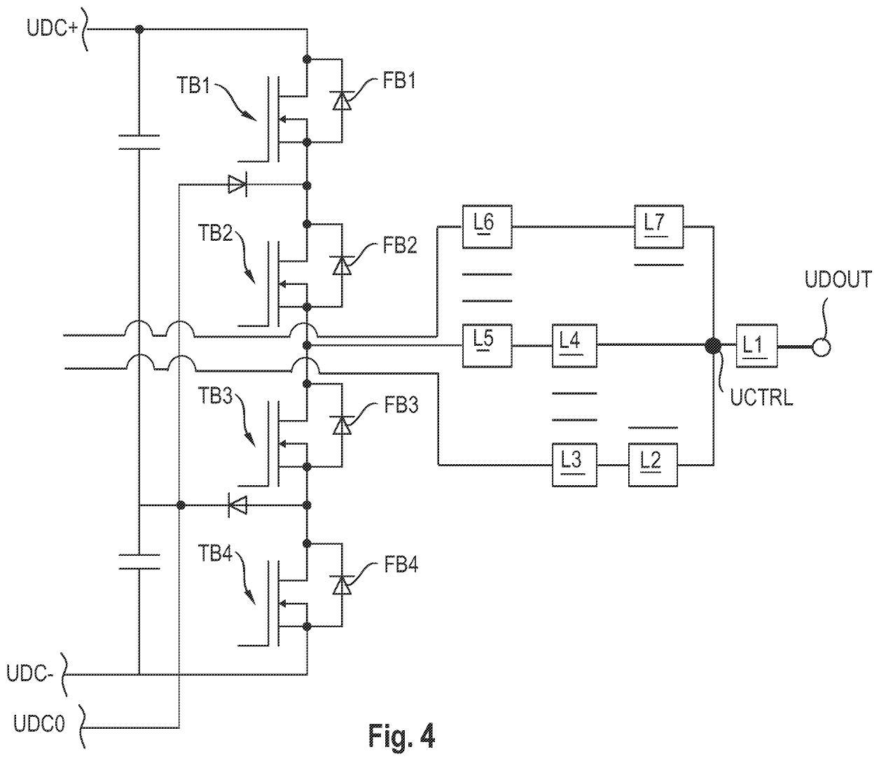

Each arm of this inductance network is provided by way of example for one bridge arm each of the converter UR, of which one such bridge arm is depicted by way of example in FIG. 4. The bridge arm depicted in FIG. 4 is connected to the middle path of the inductance network. Additional bridge arms are connected to the other paths of the inductance network so that the three partial currents of the three arms are then combined through the coupling inductance L1.

Present at the converter UR is the reference voltage UDC0, which is present at ground, for example, as well as the two maximum voltages UDC+ and UDC−, which normally are larger in magnitude than the battery voltages UBAT+ and UBAT−. The converter UR is supplied with these voltages and provides the corresponding phase currents IL to the control unit SG. These phase currents IL are alternating currents that are produced by the converter UR in the inductance emulator IE.

In a simplified circuit diagram, FIG. 3 shows the inductance emulator IE, the test device PE, and the control unit SG with the emulated battery B. The reference potential UDC0 is present in the center at the battery B, and the battery voltages UBAT+ and UBAT− are each present on the outside. This DC voltage is converted into an AC voltage, which is then present as output voltage UDOUT, by the inverter composed of the power switches T1 and T2 that are driven by components that are not shown, for example with the known pulse width modulation. The inductance emulator IE supplies the current IL that matches this output voltage UDOUT. The output voltage UDOUT is supplied by the test device PE to an inductance model IM with which the current control CC of the current IL is then controlled. The current IL is influenced through the control variable UCTRL. For this purpose, the corresponding elements in the bridge circuit are then selected with the level selector LS. In the example depicted, seven levels are possible for UCTRL: UDC+, 2/3 UDC+, 1/3 UDC+, UDC0, 1/3 UDC−, 2/3 UDC−, and UDC−. This is a seven-level power converter that can provide a control voltage as control variable UCTRL in the aforementioned seven voltage levels. The coupling inductance L1 in turn is wired between the output voltage UDOUT of the control unit SG and control variable UCTRL.

The inductance emulator IE and the test device PE, in particular the current control CC, the level selector LS, and/or the inductance model IM, can be designed at least partly as software.

The bridge depicted in FIG. 4 has four power switches, TB1 to TB4, each of which has a freewheeling diode, FB1 to FB4, connected in parallel therewith. The reference potential UDC0 is wired between the power switches TB1 and TB2 and between the power switches TB3 and TB4, respectively. The potential UDC+ can be made available at the output of the bridge by switching on TB1 and TB2. The potential UDC− can be made available at the output of the bridge by switching on TB3 and TB4.

A DC link of the circuit has two capacitors between the voltages UDC+ and UDC−. The DC link is divided and has a connection to the reference potential UDC0 in the center between the two capacitors. Two diodes are provided between the reference potential UDC0 and the connections between the respective power switches. The center potential of the DC link UDC0 can be made available at the output of the bridge through the diodes by switching on TB2 and TB3 and switching off TB1 and TB4.

Additional bridges wired in parallel—not shown in FIG. 4—can be constructed accordingly. Provided that they are constructed like the depicted bridge, they can likewise make these three potentials available at their respective outputs.

Using the bridge arm shown with two power switches TB1, TB2 and TB3, TB4 on each half bridge, it is thus possible to set three levels of the voltage: UDC+, UDC0, and UDC−. This is a three-level NPC bridge.

Three arms of an inductance network with the inductances L2 to L7—connected between the converter UE and the coupling inductance L1—are depicted in FIG. 4. These inductances L2 to L7 have iron cores. Also depicted—by means of the dashes—are iron cores that are associated with the inductances L2 to L7. The respective inductances L5/L6, L3/L4, and L2/L7 are magnetically coupled through the iron cores. The connection to the control unit SG is accomplished through the coupling inductance L1.

Each arm of this inductance network is provided by way of example for one bridge of the converter UE in each case, of which one such bridge is depicted by way of example in FIG. 4. Additional bridges are connected to the other arms of the inductance network, so that the three partial currents of the three arms are then combined through the coupling inductance L1.

The bridge depicted in FIG. 4 supplies the middle arm of the inductance network from FIG. 4 having the inductances L4 and L5 with a current that is combined with the other two arms. The other two arms are supplied with a respective current from the other two bridges, which are not shown. For this reason, the net current of the three arms flows through the coupling inductance L1 to the output A.

The inductance network consisting of the coupled inductances L5/L6, L3/L4, and L2/L7 has two fundamental functions here. Firstly, it is intended to prevent cross-currents between the parallel bridges. In addition, it serves as an inductive voltage divider in order to combine the three discrete voltages of a given bridge, of a 3L-NPC bridge in the depicted example. A seven-level topology, for example, is thus created with the aid of this voltage divider by combining, e.g., three bridges. Seven discrete voltage levels, for example, can thus be switched as the control voltage UCTRL ahead of the series inductance L1 through combination of different voltage levels from the different bridges.

If the inductance emulator is to act as a voltage source, then a capacitor can additionally be wired behind the coupling inductance L1, for example.

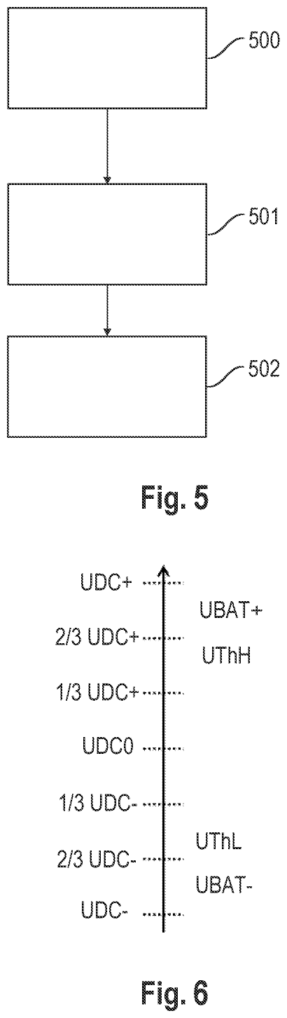

FIG. 5 shows the method according to the application in a flowchart. In method step 500, the analysis of the output voltage UDOUT of the control unit SG by the test device PE takes place. Then the value of the control variable UCTRL is defined from this in method step 501, which value then influences the phase current IL. In method step 502, the control variable UCTRL thus specified is produced by the power electronic circuit, which is designed as a bridge circuit in the depicted example.

FIG. 6 shows an ordinate that is divided in half in the center by the reference potential UDC0. The maximum values UDC+ and UDC− are the respective maximum values on this coordinate in the positive and negative directions. UBAT+ and UBAT− are each smaller in magnitude than the voltages UDC+ and UDC−, the threshold values UThH and UThL are, e.g., approximately 10 V in magnitude below the battery voltages UBAT+, UBAT−. The output voltage UDOUT is compared with these thresholds UThH and UThL. In addition, the reference potential UDC0 can also be used as a threshold value. Still more threshold values are possible. The allowed value range for the control variable UCTRL is then selected in accordance therewith (control variable limitation). In the example depicted, seven values are possible. More or fewer are also possible.

In this context, the following rules for limiting the control variable UCTRL can be given:

A: If the control variable UDOUT is greater than UThH, then only the levels for which UCTRL>UThL may be used for the current control.

B: If the control variable UDOUT is less than UThL, then only levels for which UCTRL<UThH may be used for the current control.

C: Otherwise, only levels for which UThL<UCTRL<UThH may be used for the current control. For simplification, the center voltage UDC0 can also be required for UCTRL in rule C.

The behavior at shutoff of both power switches T1 and T2 of the half bridges of the control unit SG is as follows:
Case one: current IL is positive.

At shutoff of the power switches T1 and T2, the current IL flows through the diode of T1, which is to say F1, until the inductance model IM defines a current setpoint of zero or less than zero.

Once the current IL is equal to zero, exactly the voltage UCTRL is established at UDOUT. The reason for this is that the switches T1 and T2 are switched off, and no current is flowing through the freewheeling diodes. As a result, the coupling inductance L1 is connected with high resistance on one side and the output voltage UDOUT assumes the potential of UCTRL. Then IL is equal to zero and UDOUT is equal to UCTRL.

As long as current is still flowing, however, rule A applies because the diode of T1 is conducting, and thus UDOUT>UBAT+>UThH. Because of this rule A, UCTRL is always >UThL.

When current IL=0 and UDOUT=UCTRL>UThH, rule A initially continues to apply. This state is a transition state. With such a high control voltage UCTRL, a negative current builds up in the model IM at some point, with the result that the current control CC pulls the control voltage UCTRL down. This in turn allows rule C to take effect.

When current IL=0 and UDOUT=UCTRL<UThH, rule C applies from then on, and UDOUT=UCTRL is perforce located between UThL and UThH thereafter.
Case two: current IL is negative.

At shutoff of the power switches T1 and T2, the current IL (freewheeling current) flows through the diode F2 of T2 until the inductance model IM calculates a current setpoint of zero or greater than zero.

Once the current IL is equal to zero, exactly the voltage UCTRL is established at UDOUT (see case one above).

As long as current is still flowing, however, rule B applies because the diode of T2 is conducting, and thus UDOUT<UBAT−<UThL. Because of this rule B, UCTRL is always less than UThH.

When current IL is equal to zero and UDOUT=UCTRL<UThL, rule B initially continues to apply. This state is a transition state. With such a large negative control voltage UCTRL, a positive current builds up in the model IM at some point, with the result that the current control pulls the control voltage UCTRL up. This in turn allows rule C to take effect.

When current IL is equal to zero and UDOUT=UCTRL>UThL, rule C applies from then on, and UDOUT=UCTRL is perforce located between UThL and UThH thereafter.

In both cases, the control variable limitations on UCTRL have the result that the voltage UDOUT remains between the thresholds UThL and UThH. This in turn prevents a current buildup in the coupling inductance L1 because both diodes are reverse-biased:

UDOUT=UCTRL<UThH<UBAT+, upper freewheeling diode F1 is reverse-biased, and UDOUT=UCTRL>UThL>UBAT−, lower freewheeling diode F2 is reverse-biased.

A stable state UDOUT=UCTRL arises, and the current IL is equal to zero. The current control CC now can no longer control current and the phase current IL remains at zero because both freewheeling diodes F1, F2 are reverse-biased for UThL<UDOUT<UThH.

In this way, the state of the open power switches T1, T2 of the control unit SG and the accompanying high-resistance output for UDOUT are detected. The information can continue to be used for correct emulation of the electric motor, for example in the inductance model IM. Moreover, in this way the inductance with a current of exactly zero is correctly emulated, even without controller intervention.

The behavior when the power switches T1 and T2 are switched back on can manifest as follows:

The voltage UDOUT is forced back to UBAT+ or UBAT− by the switch T1 or T2. The current control CC may once again set all levels for the control variable UCTRL that are necessary for current control in accordance with the above rules A or B.

The power switch state that at least one switch is active is therefore detected. This information can continue to be used for correct emulation of the electric motor, once again in the inductance model IM, for example.

When rule C is active, preferably the control variable UCTRL is chosen such that the induced voltage of the emulated phase currents IL is reproduced at UDOUT as a result.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A test arrangement to emulate phase currents of an electric motor to test a power electronic control unit that is equipped to drive an electric motor and is connectable to the test arrangement, the test arrangement comprising:
an inductance emulator that simulates the electric motor as an electrical load for the control unit via a power electronic circuit, the inductance emulator acting as a current source with a phase current as output current; and
a test device to influence a phase current of the inductance emulator as a function of an analysis of a quantity that depends on an output voltage of the control unit, the test device performing the analysis such that the output voltage is compared with multiple or three voltage ranges, and a respective range for a control variable of the phase current is specified depending on the voltage range in which the output voltage of the control unit is located, the control variable being a control voltage that influences the phase current.

2. The test arrangement according to claim 1, wherein the performance and/or the result of the analysis of the output voltage depends on a battery voltage that is present at the control unit and/or on a maximum voltage present at the inductance emulator.

3. The test arrangement according to claim 2, wherein a magnitude of the maximum voltage present at the inductance emulator is greater than the battery voltage.

4. The test arrangement according to claim 1, wherein the inductance emulator has an inductance network.

5. The test arrangement according to claim 1, wherein the circuit is a converter that uses at least three different values for the control variable of the phase current.

6. The test arrangement according to claim 5, wherein the converter has three bridges connected in parallel to one another, each with four or six power switches.

7. The test arrangement according to claim 1, wherein the test device for the analysis of the output voltage has a threshold comparator that has an upper and a lower threshold value, wherein the test device selects the range for the control variable of the phase current as a function of these threshold comparisons of the output voltage.

8. The test arrangement according to claim 4, wherein the inductance network is connected to a coupling inductance at whose output to the control unit the output voltage is present and at whose output in the direction of the inductance network the control variable of the phase current is present.

9. A method for testing a power electronic control unit that is connected to a test arrangement that is equipped to emulate the phase currents of an electric motor, the method comprising:
providing an inductance emulator that simulates the electric motor as an electrical load for the control unit via a power electronic circuit, the inductance emulator acting as a current source with a phase current as an output current;
providing a test device to influences the phase current as a function of an analysis of an output voltage of the control unit,
performing, via the test device, the analysis such that the output voltage is compared with multiple or three voltage ranges; and
specifying a respective range for a control variable of the phase current depending on the voltage range in which the output voltage is located, the control variable being a control voltage that influences the phase current.

10. The method according to claim 9, wherein a performance and/or a result of the analysis depends on a battery voltage that is present at the control unit and/or on a maximum voltage present at the inductance emulator.

11. The method according to claim 9, wherein the inductance emulator has a converter that uses at least three different values for the control variable of the phase current.

12. The method according to claim 9, wherein the test device for the analysis of the output voltage of the control unit has a threshold comparator that has an upper and a lower threshold value, wherein the test device specifies the value for the control variable of the phase current as a function of these threshold comparisons of the output voltage.
